(19) United States
(12) Patent Application Publication
(10) Pub. No.: US 2012/0037410 A1
(43) Pub. Date: Feb. 16, 2012

(54) THERMOPLASTIC RESIN COMPOSITION, ADHESIVE FILM AND WIRING FILM USING THE SAME

(75) Inventors: Satoru Amou, Hitachi (JP); Kosuke Kuwabara, Tokai (JP); Nobuhito Akutsu, Hitachi (JP); Tomiya Abe, Hitachi (JP)

(73) Assignee: Hitachi Cable, Ltd.

(21) Appl. No.: 13/206,560

(22) Filed: Aug. 10, 2011

(30) Foreign Application Priority Data
Aug. 12, 2010 (JP) 2010-180742

(51) Int. Cl. H05K 1/00; C09J 7/02; C08K 5/3417; C08L 71/12; C08L 75/00; C08K 5/03; B32B 7/02; H01B 7/08

(52) U.S. Cl. 174/258; 428/214; 174/117 F; 525/131; 525/130; 524/81; 524/94

(57) ABSTRACT

A thermoplastic resin composition including a polyphenylene ether-based polymer having hydroxyl groups in its chemical structure and having 2,6-dimethylphenylene ether as a repeating unit, an isocyanate compound having a plurality of isocyanate groups in its structure; or a reaction product of the polyphenylene ether-based polymer having 2,6-dimethylphenylene ether as a repeating unit and the isocyanate compound having a plurality of isocyanate groups in its structure; and a hydrogenated styrene-based elastomer, and an adhesive film and a wiring film using the same are disclosed.

### CLAIM OF PRIORITY

The present application claims priority from Japanese patent application serial No. 2010-180742, filed on Aug. 12, 2010, the content of which is hereby incorporated by reference into this application.

### FIELD OF THE INVENTION

The present invention relates to a thermoplastic resin composition having a low dielectric constant, a low dissipation factor and excellent adhesiveness to a substrate film or a conductor wiring, an adhesive film and a wiring film such as a flexible flat cable using the same.

### BACKGROUND OF THE INVENTION

Recently, electronics devices have become smaller, thinner and lighter. For a circuit board used for the electronics devices, a high density and microscopic wiring having a multi-layer structure, a microscopic wiring structure and thin shape structure is required. For one example of this wiring technology, a flexible flat cable (abbreviated as FFC) formed by forming a plurality of conductor wirings on a substrate film in parallel, covering the conductor wirings with an insulating resin and further locating a conductor layer on its outer layer as a shield layer is known, as described in Japanese Utility Application Publication No. Hei 01-095014 (Patent Document 1). The insulating resin functions as an adhesive layer which bonds the conductor wirings and the substrate film. A polyester film, a polyimide film and a polyamide film are preferably used for the substrate film. Various types of plastic films or coating compositions can be used for the insulating resin (hereinafter referred to as an adhesive layer).

On the other hand, in imaging devices as represented by a liquid crystal display and a plasma display, use of high frequency wave is progressed with providing high-definition image. Therefore, a wiring film adapted to wiring in a thin-shaped housing such as FFC is also required to correspond to electric signals in GHz band. Transmission loss of electric signals is represented as sum of dielectric loss, conductor loss and radiation loss. There is a relation in which, as the frequency of the electric signal becomes higher, the dielectric loss, the conductor loss and the radiation loss become larger. In a wiring which treats high-frequency signals, technique to suppress increase in the dielectric loss, the conductor loss and the radiation loss is required because the transmission loss attenuates the electric signals and impairs reliability of the signals.

The dielectric loss is proportional to a product of a square root of a dielectric constant of an adhesive layer covering a circuit, a dissipation factor and a frequency of the used signal. Consequently, increase in the dielectric loss can be suppressed by selecting a substrate film and an adhesive having a low dielectric constant and a low dissipation factor.

In FFC, there is an example in which a foamed elastic body is used as a substrate film as described in Japanese Patent Application Publication No. 2003-031033 (Patent Document 2). This is a technology of decreasing a dielectric constant by forming void pores in the substrate film. By this technology, the dielectric constant of the substrate film can be decreased to about 1.5 and high-speed transmission can be realized. In Patent Document 2, a rectangular copper wiring plated with tin or other metals as a conductor wiring and a foamed polyethylene terephthalate film as a foamed substrate film are further disclosed. Moreover, placing an adhesive layer on the substrate film and placing a shield layer on an outer layer of FFC which is a final product are disclosed.

In Japanese Patent Application Publication No. 2008-198592 (Patent Document 3), a polyester resin, a polyphenylene sulfide resin, a polyimide resin and the like are disclosed as a substrate film and a polyester resin containing a flame retardant agent as an adhesive layer is disclosed. Moreover, in Patent Document 3, a low dielectric layer including a resin selected from polycarbonate, polyphenylene ether, polyphenylene sulfide, polyimide, polyether imide, polyarylate, a fluorocarbon resin, a styrene-based elastomer and an olefin-based elastomer is placed on the surface of the substrate film not having an adhesive layer is disclosed. This technology is a technology which decreases a dielectric constant of a whole film by placing the low dielectric layer.

A problem of these technologies includes improvement of dielectric characteristics of the adhesive layer itself. More specifically, the problem lies in that, although a dielectric constant of the whole adhesive film can be decreased and high-speed transmission can be realized by applying the substrate film having a porous structure and a low dielectric layer in related arts, increase in transmission loss is unavoidable because a dielectric constant and a dissipation factor of the adhesive layer which directly contacts with a conductor wiring are high. For wiring films such as FCC having the adhesive layer, decrease in the dielectric constant and the dissipation factor of the adhesive layer for corresponding to using higher frequency wave in future is an important problem.

In Japanese Patent Application Publication No. 2007-323918 (Patent Document 4), thermosetting resins such as a polyester-based resin, a polyether-based resin and an epoxy-based resin, and thermoplastic resins such as a polystyrene-based resin, a vinyl acetate-based resin, an AVB-based resin, a polypropylene-based resin, a polyethylene-based resin, a polyester-based resin and a PVC-base resin as a adhesive layer are disclosed. Use of low-polar polymers such as polystyrene, polyethylene and polypropylene as the adhesive layer is effective in decrease in transmission loss because both of the dielectric constant and the dissipation factor of the adhesive layer become low. However, these low-polar polymers have low adhesion force to a conductor wiring or a substrate film. Therefore, improvement of this adhesion force is required.

In Japanese Patent Application Publication No. 2006-156243 (Patent Document 5), an adhesive film having three layers structure of adhesive layers considering flame retardant property and adhesiveness as well as electric properties is disclosed. In Patent Document 5, an adhesive layer made by a resin composition formulating 25% by weight or more of a crystalline polyester and 1 to 50% by weight of a modified polyolefin as base resins is disclosed. Moreover, a flame retardant adhesive layer made by formulating various flame retardant agents is disclosed. However, a content rate of the modified polyolefin is required to be maintained in low rate in order to ensure adhesion force in this disclosed technology. Therefore, there is limitation of decrease in a dielectric constant and a dissipation factor of the adhesive layer.

Improvement of adhesion force to various substrate films and conductor wirings as well as decrease in a dielectric constant and a dissipation factor are required for the adhesive applied for wiring films such as FFC corresponding to high-frequency signals.

An object of the present invention is to provide a thermoplastic resin composition having a low dielectric constant and a dissipation factor and having high adhesion force to conductor wirings, and an adhesive film supported on a substrate film using the composition as an adhesive layer, and moreover, a wiring film such as FFC which satisfies both high adhesion reliability and low transmission loss produced by using this adhesive film.

### SUMMARY OF THE INVENTION

The inventors of the present invention have noticed a styrene-based elastomer, which is easy to form varnish and has a low dielectric constant and a dissipation factor, as a base resin for the adhesive layer. Particularly, a hydrogenated styrene-based elastomer having whole hydrocarbon skeleton is preferable because of an excellent dielectric constant of about 2.2 to 2.3 and a dissipation factor of 0.001 to 0.002 at 10 GHz. However, evaluation of its adhesion force after placing the styrene-based elastomer as an adhesive layer on a polyethylene terephthalate film results in low adhesion force in a 180° peeling test. As a result of investigation for peeling mode, the test specimen is peeled off from the interface. Therefore, insufficient adhesion force between the adhesive layer and the substrate film is confirmed.

The inventors consider that this problem can be improved by forming primary bonds between the substrate film and the adhesive layer. Generally, in painting field, functional groups such as carboxyl groups and hydroxyl groups are introduced by performing surface treatment such as plasma treatment, corona treatment, UV and ozone treatment and flame treatment and the surface becomes hydrophilic, and thereby adhesiveness between paint and the substrate is improved. When the same treatment is applied to a substrate film such as a polypropylene film, a polyethylene terephthalate film, a polyphenylene sulfide film, a polyimide film, a polyamide-imide film, a polyether ether ketone film and a liquid crystalline polymer film, generation of carboxyl groups and hydroxyl groups is confirmed. Therefore, the inventors considered that both of an adhesive layer having high adhesion force and a low dielectric constant and a low dissipation factor can be realized, if modification which can form chemical bonds with carboxyl group or hydroxyl groups can be applied to the styrene-based elastomer without impairing its dielectric characteristics.

Next, modification of the styrene-based elastomer is described. A styrene-based elastomer has no functional groups which can directly form chemical bonds with carboxyl groups or hydroxyl groups. Consequently, the inventors investigate formulation of a polyphenylene ether-based polymer and modification for hydroxyl groups which the polyphenylene ether-based polymer has as a simple modification methods for the styrene-based elastomer. The polyphenylene ether-based polymer has good compatibility with a styrene-based elastomer and has a relatively low dielectric constant and a dissipation factor. Therefore, the polyphenylene-ether-based polymer is preferable as a formulation material for the styrene-based elastomer.

As a simple method for modifying the polyphenylene ether-based polymer in the present invention, isocyanate modification by using a compound having a plurality of isocyanate groups can be considered. By this modification, hydroxyl groups at the ends of a polyphenylene ether-based polymer resin are reacted with isocyanate groups, and isocyanate groups are introduced into the ends of the polyphenylene ether-based polymer through urethane bonds. The isocyanate-modified polyphenylene ether in an adhesive layer generates chemical bonds such as urethane bonds and amide bonds with hydroxyl groups and carboxyl groups on the surface of the substrate film, so that adhesion force between the adhesive layer and the substrate film can be increased.

Therefore, the inventors consider that a low dielectric constant and a dissipation factor as well as the high adhesion force can be obtained, if an amount of the added isocyanate-modified polyphenylene ether can sufficiently be decreased. Moreover, the inventors consider that adhesion force between the conductor wiring and the adhesive layer is also improved by treating the surface of the conductor wiring with a coupling treatment agent having functional groups which can react with isocyanate groups such as hydroxyl groups and amino groups.

According to the present invention, a thermoplastic resin composition having excellent adhesion force to a substrate film and conductor wirings and a low dielectric constant and a dissipation factor can be obtained. Moreover, an adhesive film having excellent adhesion force to the substrate film and the conductor wirings and the low dielectric constant and the dissipation factor can be obtained by using the thermoplastic resin composition of the present invention for the adhesive layer. By this adhesive film, a wiring film such as a flexible flat cable having excellent high-frequency transmission property, handling property and adhesion reliability can be obtained.

### BRIEF DESCRIPTION OF THE DRAWINGS

FIG. 1 is a schematic diagram showing an adhesion structure between a substrate film and an adhesive layer of the present invention;

FIG. 2 is a schematic diagram showing an adhesion structure of the first example between a conductor wiring and an adhesive layer of the present invention;

FIG. 3 is a schematic diagram showing an adhesion structure of the second example between a conductor wiring and an adhesive layer of the present invention;

FIG. 4 is a schematic diagram showing an adhesion structure of the third example between a conductor wiring and an adhesive layer of the present invention;

FIG. 5a is a structural formula of one example of a monofunctional polyphenylene ether polymer used in the present invention;

FIG. 5b is a structural formula of another example of a monofunctional polyphenylene ether polymer used in the present invention;

FIG. 6a is a structural formula of one example of a multifunctional polyphenylene ether polymer used in the present invention;

FIG. 6b is a structural formula of another example of a multifunctional polyphenylene ether polymer used in the present invention;

FIG. 7 is a schematic diagram showing a multilayer structure of an adhesive film of the present invention;

FIG. 8 is a perspective view of a flexible flat cable (FFC) to which the present invention is applied;

FIG. 9 is a perspective view of the end of FFC to which the present invention is applied;

FIG. 10 is a cross-sectional view of the end of FFC to which the present invention is applied;

FIG. 11 is a graph showing relation between a contact angle on a substrate surface and treatment time when providing hydrophilic property by surface treatment;

FIG. 12 is a cross-sectional view showing a structure of a wiring film according to one example of the present invention; and

FIG. 13 is a cross-sectional view showing a structure of a wiring film according to another example of the present invention.

### DETAILED DESCRIPTION OF THE PREFERRED EMBODIMENTS

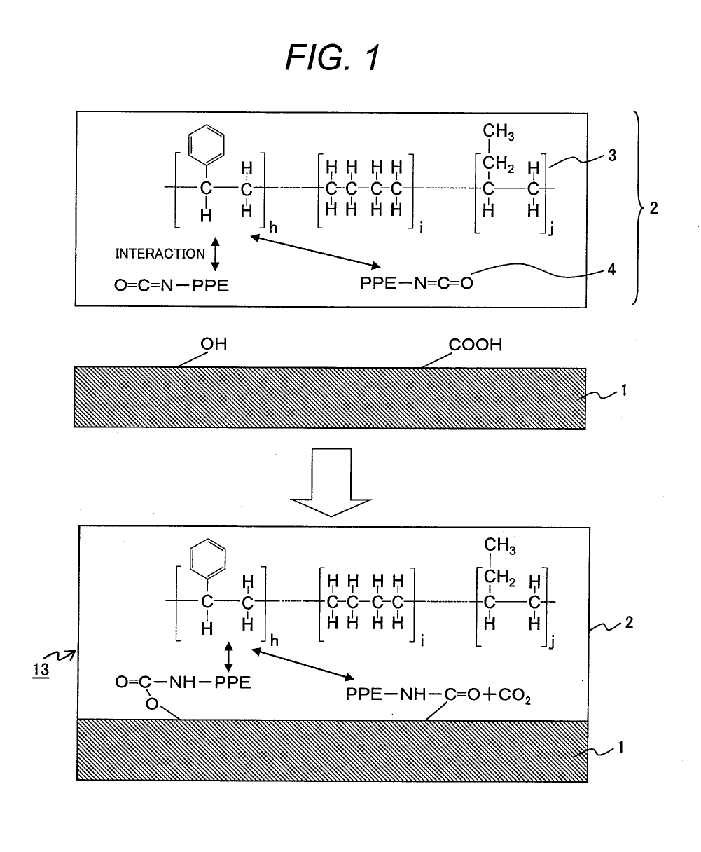

Hereinafter, the present invention is described in detail by referring to the drawings. In FIG. 1, an adhesion interface structure between an adhesive layer and a substrate film when the thermoplastic resin composition of the present invention is used for the adhesive layer is schematically shown. Functional groups having active hydrogens such as amino groups, amide groups, hydroxyl groups and carboxyl groups are formed on the surface of the substrate film 1. In the case of a substrate film 1 not having these functional groups, hydroxyl groups and carboxyl groups are generated by hydrophilic treatment such as UV and ozone treatment, corona treatment and plasma treatment.

On the other hand, in the adhesive layer 2 of the present invention, styrene units in a hydrogenated styrene-based elastomer 3 and polyphenylene ether units in an isocyanate-modified polyphenylene ether 4 which are main components are interacted with each other. Both polymers become compatible and generate high adhesion force. When the adhesive layer 2 of the present invention is placed on the substrate film with hydrophilic treatment, covalent bonds between isocyanate groups in the adhesive layer 2 and hydroxyl groups, carboxyl groups, amino groups, amide groups and the like on the surface of the substrate film are generated. The hydrogenated styrene-based elastomer which is a main component in the adhesive layer is strongly bonded to the substrate film through the isocyanate-modified polyphenylene ether, and adhesion force between the adhesive layer and the substrate film increases. In the present invention, there is no need to modify all hydroxyl groups in the polyphenylene ether-based polymer included in the adhesive layer to isocyanate groups.

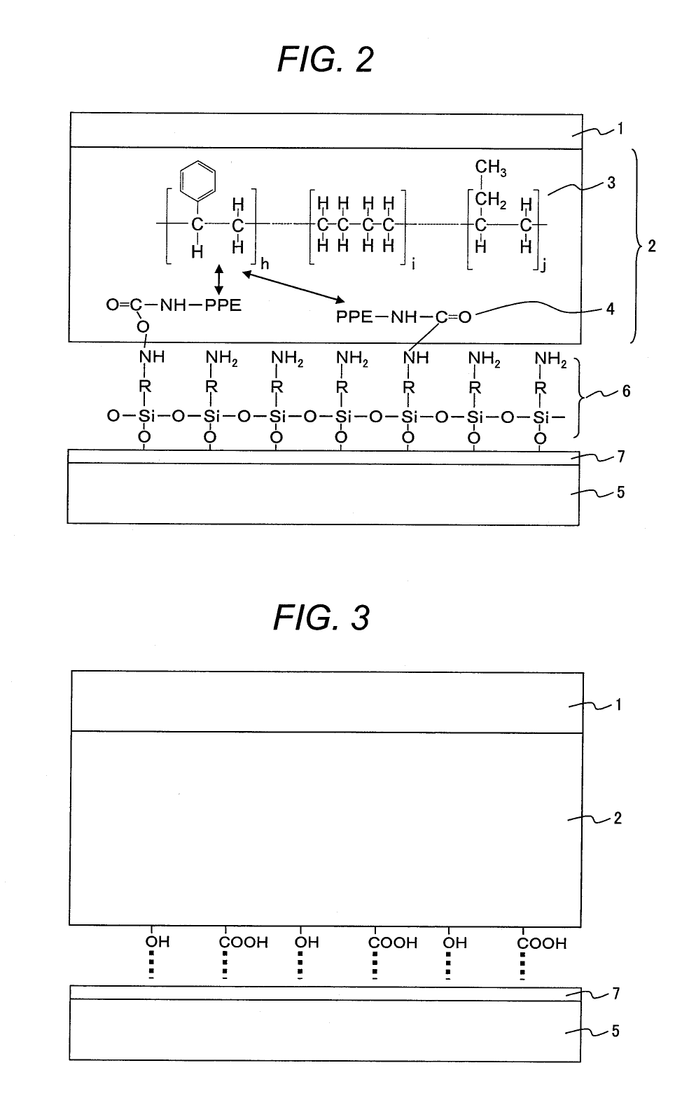

In FIG. 2, the first example of an adhesion interface structure between the adhesive layer 2 and a conductor wiring 5 of the present invention is schematically shown. On the surface of the conductor wiring 5, functional groups such as hydroxyl groups, carboxyl groups, isocyanate groups, amino groups and amide groups which can form chemical bonds with hydroxyl groups or isocyanate groups at the ends of polyphenylene ether in the adhesive layer are introduced by silane coupling treatment. In FIG. 2, amino silane treatment is shown as a representative example. When the conductor wiring 5 is made of copper, a dissimilar metal layer 7 formed by such as tin, zinc, cobalt and nickel, and its preferable oxide/hydroxide layers is preferably formed between a silane coupling treatment layer 6 and the conductor wiring 5.

This oxide/hydroxide generates chemical bonds between the conductor wiring 5 and the silane coupling agent layer 6 and has an effect to increase in adhesion force. Functional groups which the silane coupling treatment layer 6 has and the isocyanate-modified polyphenylene ether 4 in the adhesive layer form covalent bonds at a heat-lamination process, or if necessary, a heating process thereafter. By these processes, the adhesive layer 2 and the conductor wiring 5 are bonded strongly.

In FIG. 3, the second example of an adhesion interface structure between the adhesive layer and the conductor wiring of the present invention is schematically shown. In this example, a method for applying similar hydrophilic treatment to the surface of the adhesive layer 2 placed on the substrate film 1 and introducing polar groups such as hydroxyl groups and carboxyl groups is shown. Through the introduced polar groups on the surface of the adhesive layer 2, the adhesive layer 2 and the dissimilar metal layer 7 and its oxide/hydroxide layer 8 (omitted in FIG. 3) existing on the surface of the conductor wiring 5 are adhered by van der Waals' force. In FIG. 3, an example in which hydroxyl groups and carboxyl group coexist is shown.

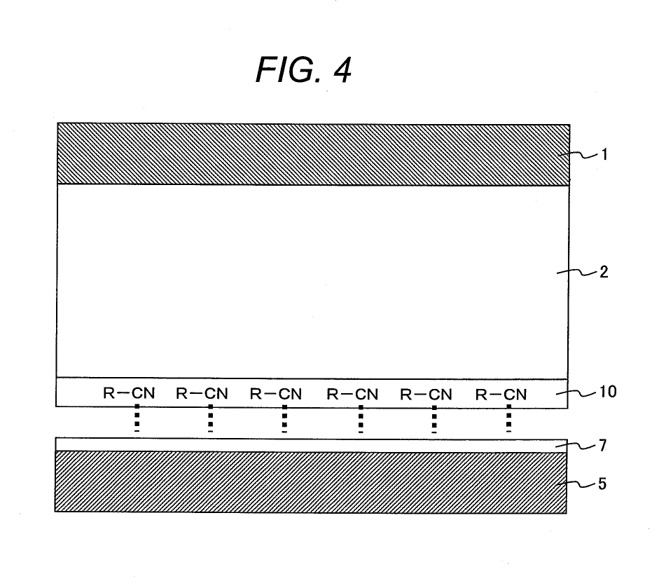

In FIG. 4, the third example of an adhesion interface structure between the adhesive layer and the conductor wiring of the present invention is schematically shown. This example is a method for placing a primer layer 10 for the conductor wiring (the third adhesive layer) on the surface of the adhesive layer 2. Through the primer layer 10 for the conductor wiring, the adhesive layer 2 and the dissimilar metal layer 7 and its oxide/hydroxide layer 8 (omitted in FIG. 4) existing on the surface of the conductor wiring 5 are adhered by van der Waals' force. In FIG. 4, an example of a compound which has nitrile groups in its structure as a representative example.

The present invention further includes roughening treatment to the surface of the conductor wiring as another method for increasing adhesion force between the adhesive layer 2 and the conductor wiring 5. As methods for roughening treatment, known etching treatment, granular plating process, black oxide and reduction treatment, treatment using Neo Brown and the like can be used. These methods are preferable because adhesion force between the adhesive layer and the conductor wiring can be improved with suppressing increase in conductor loss and moreover layer configuration at the interface can also be simplified by roughening the surface of the conductor wiring in the range of 0.1 μm to 2 μm measured by average surface roughness Ra. The roughening treatment of the surface of the conductor wiring and the silane coupling treatment, the hydrophilic treatment of the surface of the adhesive layer 2 and the placement of the primer layer 10 for the conductor wiring can be used in combination.

The present invention includes following embodiments.

(1) A thermoplastic resin composition of the present invention is a thermoplastic resin composition including: (I) a polyphenylene ether-based polymer having hydroxyl groups in its chemical structure and having 2, 6-dimethylphenylene ether as a repeating unit; (II) an isocyanate compound having a plurality of isocyanate groups in its structure; and (III) a hydrogenated styrene-based elastomer. In other words, the thermoplastic resin composition of the present invention includes (I) to (III) as essential components.

(2) A thermoplastic resin composition includes (IV) a reaction product of the polyphenylene ether-based polymer having hydroxyl groups in its chemical structure and having 2,6-dimethylphenylene ether as a repeating unit and the isocyanate compound having a plurality of isocyanate groups in its structure; and the hydrogenated styrene-based elastomer. The reaction product (IV) can be used instead of (I) the polyphenylene ether-based polymer and (II) the isocyanate compound having a plurality of isocyanate groups in its structure in (1). In this case, the thermoplastic resin composition includes (III) and (IV) as essential components.

(3) The thermoplastic resin composition, in which the polyphenylene ether-based polymer is a diol compound having hydroxyl groups at its both ends, and the isocyanate compound is a diisocyanate compound.

(4) The thermoplastic resin composition, further comprising a catalyst which accelerates a reaction of isocyanate groups with hydroxyl groups, amino groups, amide groups and carboxyl groups.

(5) The thermoplastic resin composition, in which the composition comprises 75 to 90 parts by weight of the hydrogenated styrene-based elastomer, 10 to 25 parts by weight of the polyphenylene ether-based polymer having 2,6-dimethylphenylene ether as the repeating unit, and 1 to 20 parts by weight of the isocyanate compound having the isocyanate groups in its structure.

(6) The thermoplastic resin composition in which the catalyst is added to the thermoplastic resin composition and an amount of the added catalyst is 0.1 to 2 parts by weight to 100 parts by weight of a total amount of the resin components.

(7) The thermoplastic resin composition, in which the composition includes the hydrogenated styrene-based elastomer, composition includes the hydrogenated styrene-based elastomer, a hydrogenated acrylonitrile-butadiene rubber and/or an amorphous polyester.

(8) The thermoplastic resin composition according to (7), in which the composition includes 50 to 99 parts by weight of the hydrogenated styrene-based elastomer and 1 to 50 parts by weight of a total amount of the hydrogenated acrylonitrile-butadiene rubber or/and the amorphous polyester.

(9) The thermoplastic resin composition according to any of (1) to (8), further including one or more flame retardant agent represented by Formula 1 and/or Formula 2.

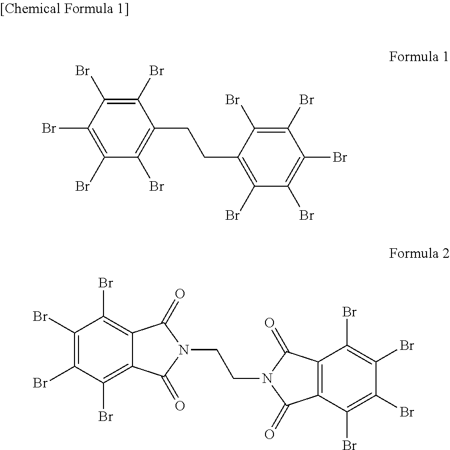

(10) The thermoplastic resin composition, in which an amount of the added flame retardant agent is 100 to 300 parts by weight to 100 parts by weight of a total amount of the resin components in the thermoplastic resin composition.

(11) An adhesive film in which at least one of the thermoplastic resin compositions according to any of (1) to (10) is laminated in a thickness of 10 to 100 μm on the substrate film having a thickness of 10 to 300 μm which is one of the films selected from a polypropylene film, a polyethylene terephthalate film, a polyphenylene sulfide film, a polyimide film, a polyamide-imide film, a polyether ether ketone film, a liquid crystalline polymer film and combinations thereof. The substrate film may be a composite film made of the above-described resins.

(12) The adhesive film, in which the film has a multilayer structure including the thermoplastic resin composition according to (1) to (9) in which a content of a flame retardant agent is 0 to 90 parts by weight as a first adhesive layer laminated on the substrate film; and the thermoplastic resin composition according to (1) to (10) in which a content of a flame retardant agent is 100 parts by weight or more as a second adhesive layer further laminated on the first adhesive layer.

(13) The adhesive film, in which an interface of the adhesive layer and the substrate film in the adhesive film includes at least any one of chemical structures selected from a hydroxyl group, a carboxyl group, an amino group, a urethane bond, a urea bond and an amide bond.

(14) The adhesive film, in which a third adhesive layer having a high polar layer including a compound having any one or more of the functional groups selected from a hydroxyl group, a carboxyl group, a nitrile group, a ketone group, an amide group and an amino group is laminated on the second adhesive layer.

(15) The adhesive film, in which the third adhesive layer includes a hydrogenated acrylonitrile-butadiene rubber.

(16) The adhesive film according to (15), in which the third adhesive layer includes a hydrogenated styrene-based elastomer.

(17) The adhesive film according to (16), in which the third adhesive layer includes an amorphous polyester.

(18) The adhesive film according to any of (14) to (17), in which the third adhesive layer further includes a flame retardant agent represented by Formula 1 or Formula 2.

(19) The adhesive film according to (14), in which the third adhesive layer is a high polar layer formed by hydrophilic treatment of the surface of the second adhesive layer.

(20) The adhesive film according to (19), in which the third adhesive layer is a high polar layer formed by any hydrophilic treatment selected from UV and ozone treatment, corona treatment and plasma treatment to the second adhesive layer.

(21) The adhesive film, in which a thickness of the first adhesive layer is 1 to 18 μm, a thickness of the second adhesive layer being 9 to 99 μm, and a thickness of the third adhesive layer being 0 to 10 μm in the adhesive layers having the multilayer structure.

(22) The adhesive film, in which a dielectric constant is 2.3 to 2.7 and a dissipation factor is 0.0015 to 0.005 in combined dielectric characteristics of the adhesive layer having the multilayer structure.

(23) A wiring film processed by laminating after sandwiching a column of conductors arranging a plurality of conductors in parallel and the surface of the column of conductors from the upper side and the lower side with two adhesive films through adhesive layers; in which the adhesive layer is made of a thermoplastic resin composition comprising: a hydrogenated styrene-based elastomer; a polyphenylene ether-based polymer having 2,6-dimethylphenylene ether as a repeating unit; and an isocyanate compound having a plurality of isocyanate groups in its structure and/or a reaction product thereof.

(24) The wiring film, in which the conductor wiring is made of copper; the surface thereof having a dissimilar metal layer selected from tin, zinc, cobalt, nickel and chromium; a surface of the dissimilar metal layer further having an oxide or a hydroxide layer made of the corresponding metal, if necessary; and the oxide or the hydroxide layer having any one of a silane coupling agent layer having amino groups, hydroxyl groups or isocyanate groups and a reaction residue of the silane coupling agent with the isocyanate compound on the oxide or the hydroxide layer.

(25) The wiring film, in which a conductor surface in the wiring film is subjected to roughening treatment.

(26) The wiring film, wherein covalent bonds and/or a high polar layer exist between the adhesive layer and the conductor wiring in the wiring film.

(27) The wiring film, in which an aluminum foil layer is placed on an outer layer of a substrate film through a conductive adhesive layer and the aluminum foil layer is electrically connected to at least one of the conductor wiring in the wiring film.

(28) A multilayer wiring film made by alternatively laminating a wiring film having a wiring pattern on at least one surface thereof and an adhesive film having adhesive layers on both surfaces thereof, in which the adhesive layer is made of a thermoplastic resin composition including: a hydrogenated styrene-based elastomer; a polyphenylene ether-based polymer having 2,6-dimethylphenylene ether as a repeating unit; and an isocyanate compound having a plurality of isocyanate groups in its structure and/or a reaction product thereof.

The method for enhancing adhesion force between an adhesive layer having a low dielectric constant and a low dissipation factor and a substrate film and a conductor wiring is previously described. Hereinafter, the substrate film, the conductor wiring and the adhesive layer are described. In order to increase adhesion force between the substrate film and the adhesive layer of the present invention, functional groups possible to react with isocyanate groups, that is, hydroxyl groups, carboxyl groups, amide groups, amino groups and isocyanate groups preferably exist on the surface of the substrate film.

As methods for simply introducing hydroxyl groups, carboxyl groups and the like on the substrate film, hydrophilic treatment such as UV and ozone treatment, corona treatment and plasma treatment is known. Hydrophilic treatment time of the substrate film depends on energy intensity of the treatment. Hydroxyl groups and carboxyl group can be introduced on the surface of the substrate film by the treatment for about 1 minute to 10 minutes. Hydroxyl groups can be converted into other functional groups such as amino groups and amide groups by applying a silane coupling agent, which is described below, to the substrate film after the hydrophilic treatment.

When a polyimide film is used as a substrate, generation of amino groups and amide groups by ring opening of imide rings with chemical treatment using aqueous alkaline solution of sodium hydroxide, potassium hydroxide and the like is also known. These functional groups having active hydrogens on these substrate films react with an isocyanate compound formulated in the adhesive layer and a polyphenylene ether-based polymer modified with the isocyanate compound and this reaction generates strong adhesion force between the substrate film and the adhesive layer. General purpose organic films previously enumerated can be used as the substrate of the adhesive film of the present invention. Among these films, a polyethylene terephthalate film is preferably used from the viewpoint of cost and versatility, and a polypropylene film is preferably used from the viewpoint of dielectric characteristics.

Although there is no particular limitation of film thickness, the thickness is selected in the range of 10 to 300 μm from the viewpoint of ease of handling and strength.

Similar to the substrate film, adhesion force between the adhesive layer and the conductor wiring can be improved by introducing functional groups which are possible to react with isocyanate groups on the surface of the conductor wiring. As a method for introducing the functional groups on the surface of the conductor wiring, chemical treatment using the silane coupling agent is the simple treatment.

When the conductor wiring is made of copper, since a copper oxide layer or a cuprous oxide layer exiting on the surface of the conductor is weak in mechanical and chemical property, these layers are preferably replaced with other stable dissimilar metal layer. Example of such dissimilar metals can include tin, zinc, nickel, chromium, cobalt and aluminum. Among these metals, tin, zinc, nickel, chromium and cobalt, which can be used in electroless plating or displacement plating, are used in a simple manner. In order to enhance reactivity with silanol groups, an oxide layer or a hydroxide layer of the dissimilar metal is preferably formed on the surface of the metal. The oxide layer or the hydroxide layer of the dissimilar metal is generated in the process of drying and washing with water. Moreover, formation of these layers may be accelerated by adding heating treatment, hot water treatment, vapor treatment, chemical treatment and plasma treatment.

A film thickness of the dissimilar metal layer is desirably 1 to 100 nm. When the thickness is 1 nm or lower, a component of the dissimilar metal may disappear by diffusing into a copper wire. On the other hand, when the thickness exceeds 100 nm, conductor loss may increase from an effect of the dissimilar metal layer which has higher electric resistance than the resistance of copper by a skin effect of high-frequency signals. By this reason, more preferable film thickness of the dissimilar metal layer is 10 nm to 50 nm. Since the metal oxide layer and/or the metal hydroxide layer is produced by modifying the dissimilar metal layer, the metal oxide layer and/or the metal hydroxide layer have a thickness of about 1 nm to 100 nm. Here, the dissimilar metal layer and the metal oxide layer and/or the metal hydroxide layer may include a plural kinds of metal atoms.

A film thickness of the silane coupling agent layer is preferably 1 to 150 nm. A film thickness of 1 nm is almost equal to a thickness of a monomolecular film. Improvement effect for adhesion force by increase in the film thickness of the silane coupling agent layer is only exerted up to 150 nm. The silane coupling agent layer is formed by applying the agent as aqueous solution or organic solvent solution on a wiring. After application, the layer is preferably dried at a temperature in the range of 100° C. to 150° C. for 10 minutes or more.

Silane coupling agents having functional groups which can react with isocyanate groups in the present invention include amine-based silane coupling agents such as N-2-(aminoethyl)-3-aminopropylmethyldimethoxy silane, N-2-(aminoethyl)-3-aminopropylmethyltrimethoxy silane, N-2-(aminoethyl)-3-aminopropylmethyltriethoxy silane, 3-aminopropyltrimethoxy silane, 3-aminopropyltriethoxy silane, 3-ureidepropyltrimethoxy silane; silane agents generating hydroxyl groups on a surface after the reaction such as tetramethoxy silane, and tetraethoxy silane; and silane agents having isocyanate groups in its structure such as 3-isocyanate-propyltriethoxy silane, and 3-isocyanate-propyltrimethoxy silane.

Further, on the conductor wiring to which the above-described surface treatment is applied, the adhesive layer of the present invention including a multifunctional isocyanate compound is previously placed in the range of 1 to 10 μm as a primer, and thereby the adhesion force between the adhesive film and the conductor wiring of the present invention can further be enhanced.

The substrate film to which the hydrophilic treatment is applied and the conductor wiring to which the chemical treatment is applied with the silane coupling agent form primary bonds with a thermoplastic resin composition including a styrene-based elastomer, a polyphenylene ether-based polymer and an isocyanate compound having a plurality of isocyanate groups in its structure (hereinafter abbreviated as a multifunctional isocyanate compound) and exerts high adhesion force.

Next, constituent components in the thermoplastic resin composition used for the adhesive layer is described. The styrene-based elastomer has an effect for reducing a dielectric constant and a dissipation factor in a system. Preferable examples include a hydrogenated styrene-butadiene copolymer which does not have 1,2- or 1,4-butadiene structure from the viewpoint of dielectric characteristics and also suppression of oxidation degradation. Such examples include Tuftec (registered trademark) H1031, H1041, H1043, H1051, H1052, H1062, H1221, H1272 and other grades manufactured by Asahi Kasei Chemicals Corporation. Among these copolymers, elastomers having an elongation of 700% or more are preferably used from the viewpoint of improvement of adhesiveness.

A polyphenylene ether-based polymer used in the present invention is a polymer having a repeating unit of 2,6-dimethylphenylene ether and having hydroxyl groups in its ends. The polymer has a function to chemically bond the adhesive layer to functional groups on the surface of the substrate film and the conductor wiring through a multifunctional isocyanate compound. A molecular weight thereof is preferably low. By this low molecular weight, adjustment of hydroxyl group concentration in the adhesive layer becomes easy as well as solubility of the polyphenylene ether-based polymer can be improved.

A preferable range of the molecular weight is 1000 to 3000 as a polystyrene-converted molecular weight. When the molecular weight significantly exceeds 3000, an excessive polyphenylene ether-based polymer is required to be added in order to adjust hydroxyl group concentration in the system. The polyphenylene ether-based polymer has high melting point. Therefore, the increase in the amount thereof may cause to rise in a laminate temperature of the adhesive film and to reduce the adhesion force. Preferable formulation ratio is 75 parts by weight to 90 parts by weight of the styrene-based elastomer and 10 to 25 parts by weight of the polyphenylene ether-based polymer. More preferable formulation ratio of the polyphenylene ether-based polymer is 10 to 20 parts by weight.

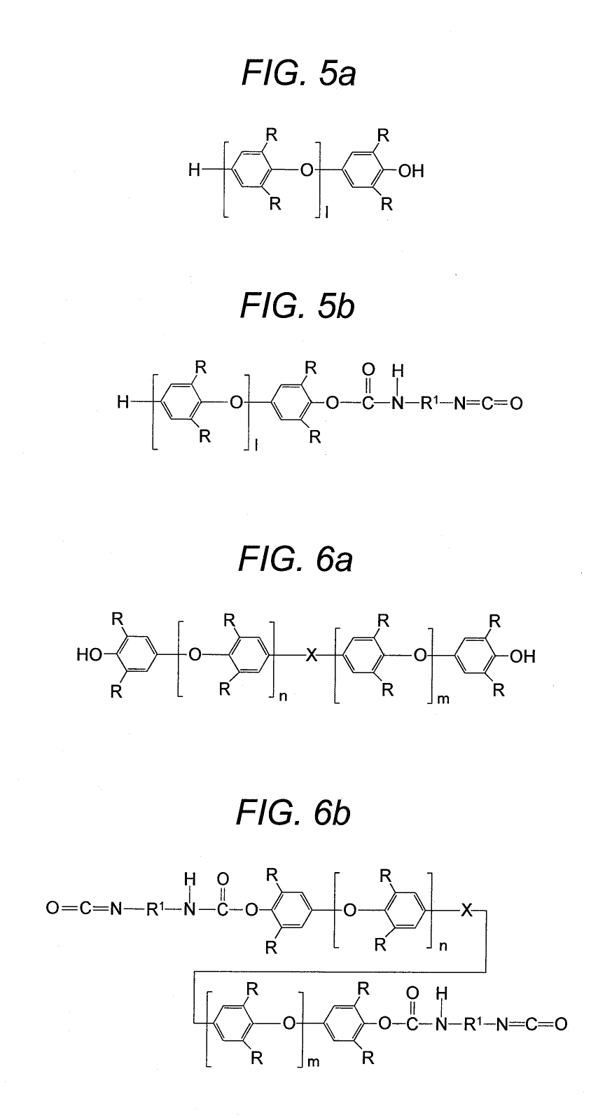

For the polyphenylene ether-based polymer used in the present invention, a polymer in which hydroxyl groups of its ends are previously modified to isocyanate groups may be used. For the polyphenylene ether-based polymer, a polymer having hydroxyl groups or isocyanate groups at its both ends illustrated in FIG. 6a and FIG. 6b is more preferably used than a monofunctional polyphenylene ether-based polymer illustrated in FIG. 5a and FIG. 5b. By having the functional groups at its both ends, strength of the adhesive layer is increased and the adhesion force can be improved because the molecular weight of the adhesive film becomes high during drying and laminating processes.

An example of a polyphenylene ether-based polymer having low molecular weight and having hydroxyl group at its both ends includes a low molecular weight polyphenylene ether-based polymer OPE (registered trademark) manufactured by MITSUBISHI GAS CHEMICAL COMPANY, INC. An example of the isocyanate-modified polyphenylene ether includes reaction compounds of OPE with various diisocyanate compounds. At the time of preparing a varnish for forming the adhesive layer, a polyphenylene ether-based polymer which is previously modified with isocyanate may be used, and a polyphenylene ether-based polymer having hydroxyl groups can also be used without any modification. This is because reactivity of an isocyanate group and a hydroxyl group is high and a reaction of the hydroxyl groups of the polyphenylene ether-based polymer with a multifunctional isocyanate compound proceeds at the time of preparing the varnish and drying the adhesive layer, and thereby modification with isocyanate is achieved.

Next, the multifunctional isocyanate compound is described. For the multifunctional isocyanate compound bonding the adhesive layer to the substrate film and the conductor wiring, and any compounds as long as compounds having a plurality of isocyanate groups contributes improvement of adhesion force. Examples of the compounds include hexamethylene diisocyanate and poly hexamethylene diisocyanate being polymer thereof, dicyclohexylmethane 4,4′-diisocyanate, 1,5-diisocyanatonaphthalene, 2,4-tolylene diisocyanate and poly (2,4-tolylene diisocyanate) being polymer thereof, trimethylhexamethylene diisocyanate, isophorone diisocyanate, and m-xylene diisocyanate. Preferable isocyanate compounds include diisocyanate compounds. This is because a three-dimensional cross-link structure is difficult to form by the reaction of diisocyanate compounds with diol compounds and fluctuation of laminatability of the adhesive layer is small. Moreover, application of a polydiisocyanate compound having high molecular weight is particularly preferable from the viewpoint of improvement effect for adhesion force.

An amount of the added isocyanate compound is preferably in the range of 1 to 20 parts by weight. This is because, since an isocyanate group, and a urethane bond and a urea bond which are reaction product of the isocyanate group with high polarity, increase in the amount thereof may deteriorate dielectric characteristics of the adhesive layer. In addition, this is because adhesion force is not improved when the amount of the isocyanate compound is further increased within the range of the above-described formulation ratio of the styrene-based elastomer and the polyphenylene ether-based polymer.

In the present invention, a curing catalyst for the isocyanate compound can be added to the adhesive layer. By adding the curing catalyst, adhesion force to the substrate film and the conductor wiring can be enhanced. Examples of the curing catalysts include tertiary amines such as triethylene diamine, bis (2-dimethylaminoethyl)ether, N,N,N′,N′-tetramethylhexamethylene diamine, N,N,N′,N″,N″-pentamethyldiethylene triamine, N-methyl-N′-(2-dimethylaminoethyl) piperazine, triethylamine, N-methylmorpholine, N-ethylmorpholine and carboxylates thereof; organometallic compounds such as metal salts of carboxylates such as lead octoate and dibutyl tin dilaurate. These compounds can preferably be used singularly or in combination of two or more. The amount of the added compound is preferably 0.1 to 2 parts by weight to 100 parts by weight of the total amount of the resin components.

To the adhesive layer, 100 parts by weight or more of, particularly in the range of 100 parts by weight to 300 parts by weight of the flame retardant agent represented by Formula 1 or Formula 2 may further be added to 100 parts by weight of the total amount of the resin. The flame retardant agent has excellent dielectric characteristics and can add flame retardant property with suppressing deterioration of the dielectric characteristics the adhesive layer. When the amount of the added flame retardant agent is less than 100 parts by weight, sufficient flame retardant property may not be exerted. On the other hand, when the amount of the added flame retardant agent exceeds 300 parts by weight, flexibility of the adhesive film may possibly be impaired. Therefore, the amount added is desirably adjusted within the range as described above.

Next, methods for improving adhesion force of the adhesive layer which is used as the third adhesive layer without using the multifunctional isocyanate compound to the substrate film and the conductor wiring are described. These methods aim to improve stability of adhesive varnish by eliminating the isocyanate compound from the adhesive layer. In the adhesive layer not using the isocyanate compound, the hydrogenated styrene-based elastomer and the hydrogenated acrylonitrile-butadiene rubber and/or the amorphous polyester are main components. The hydrogenated styrene-based elastomer contributes to improvement of dielectric characteristics of the adhesive layer, while the hydrogenated acrylonitrile-butadiene rubber mainly contributes to improvement of the adhesion force to the conductor wiring due to an effect of nitrile groups in its structure. The amorphous polyester contributes to improvement of flowability of the adhesive layer and improvement to adhesiveness to the substrate film.

Formulation ratios of each component are used in the ranges of 50 to 99 parts by weight of the hydrogenated styrene-based elastomer and 1 to 50 parts by weight of the total weight of the hydrogenated acrylonitrile-butadiene rubber and/or the amorphous polyester. As the preferable ranges which satisfy both adhesion force and dielectric characteristics, the ranges of 75 to 97.5 parts by weight of the hydrogenated styrene-based elastomer and 2.5 to 25 parts by weight of the total weight of the hydrogenated acrylonitrile-butadiene rubber and/or the amorphous polyester are exemplified. An example of the hydrogenated acrylonitrile-butadiene rubber can include Zetpol (registered trademark) 2000L, 2000, 1020, 0020 and other grades manufactured by ZEON CORPORATION. An example of the amorphous polyester can include Vylon (registered trademark) 103, 220, 300, 670, GK330, GK590 and other grades manufactured by TOYOBO CO., LTD. In the adhesive layer not including the isocyanate compound of the present invention, the flame retardant agent represented by Formula 1 or Formula 2 can be formulated as similar to the adhesive layer including the isocyanate compound.

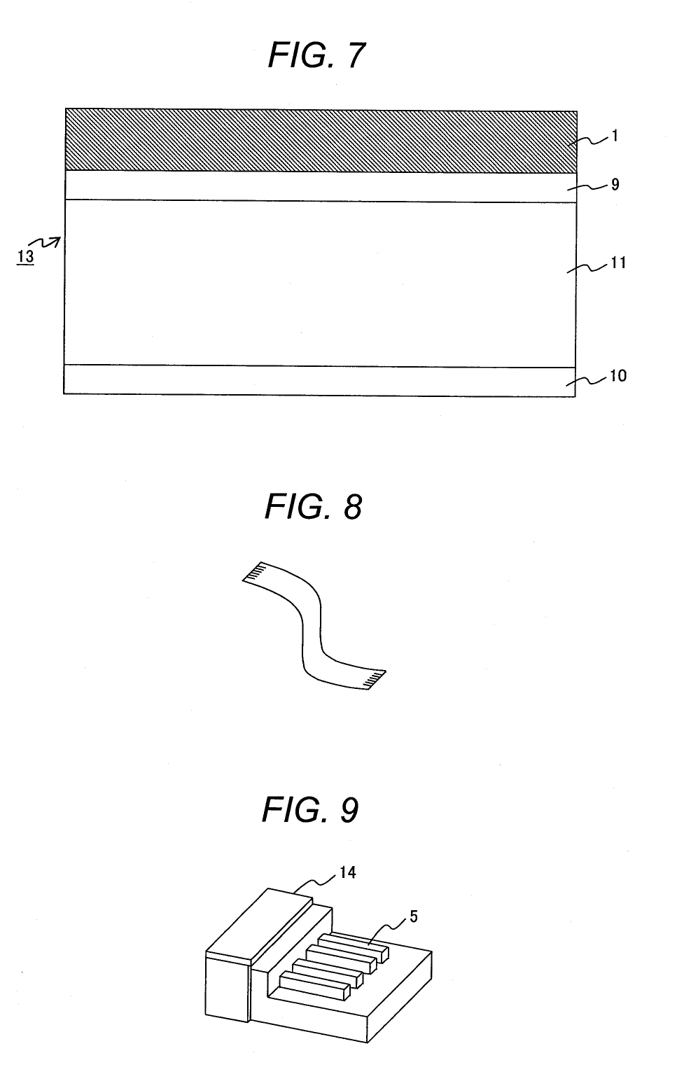

For the adhesive film of the present invention, the adhesive layer is preferably used by forming multilayer adhesive layer. This is because each layer shares its main function and performance of the whole adhesive layer can be improved. Example of this layer constitution is illustrated in FIG. 7. A first adhesive layer 9 is a primer layer for the substrate which emphasizes a function of increasing the adhesion force to the substrate film. For this layer, an amount of the added flame retardant agent represented by Formula 1 or Formula 2 in the adhesive layer is preferably in the range of 0 to 90 parts by weight, and more preferably in the range of 5 to 20 parts by weight when the total weight of the resin component is 100 parts by weight. This layer has a feature in which high adhesion force is easily obtained because of the small amount of the added flame retardant agent and a feature in which an adhesive layer 9 becomes tack-free by adding a small amount of the flame retardant agent.

A second adhesive layer 11 is a layer which contributes to lower dissipation factor of the adhesive layer and providing flame retardant property to the adhesive film. For this layer, an amount of the added flame retardant agent represented by Formula 1 or Formula 2 in the adhesive layer is preferably in the range of 100 to 300 parts by weight when the total weight of the resin component is 100 parts by weight. This layer also contributes to providing tack-free property of the third adhesive layer 10 by forming microscopic irregularity on the surface of the adhesive layer due to an effect of the highly filled flame retardant agent. The third adhesive layer 10 has a feature in which adhesion force between the conductor wiring on which roughening treatment is not performed and primer is not placed and the adhesive layer is improved.

The third adhesive layer 10 is a layer including a polar component. This layer may be formed by applying the hydrophilic treatment to the second adhesive layer 11 as described above, or formed by newly placing an adhesive layer made by formulating the hydrogenated styrene-based elastomer and the hydrogenated acrylonitrile-butadiene rubber and the amorphous polyester. In the present invention, there is one of the characteristic points in that the hydrogenated styrene-based elastomer is commonly formulated in each layer. By this formulation, since each adhesive layer becomes compatible at the time of forming multilayer as well as the dielectric constant and the dissipation factor in each layer is reduced, the adhesion force is improved.

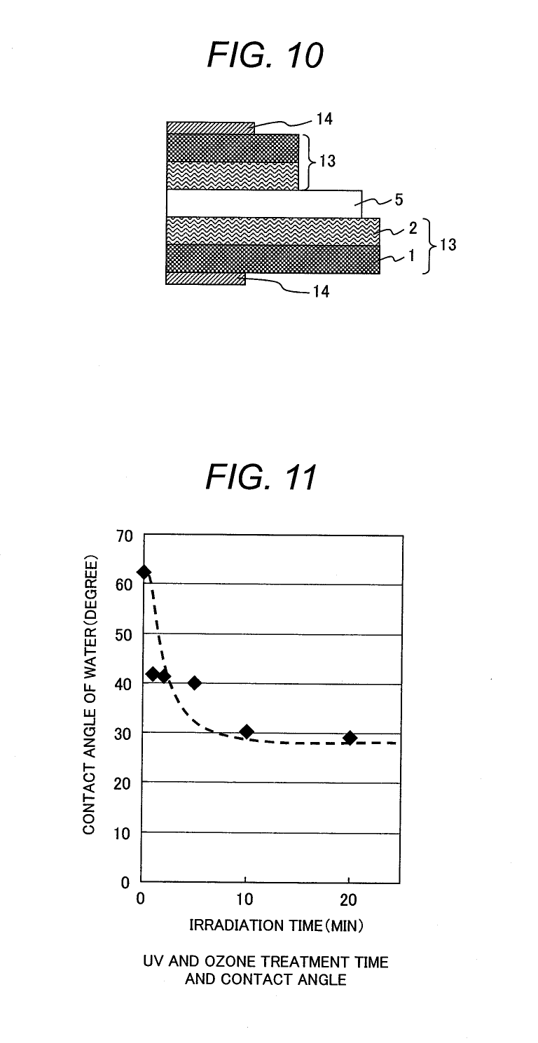

Firstly, FFC can be included as an example of a wiring film of the present invention. A perspective view of FFC, a perspective view of the end part of FFC and a cross-sectional view of the end part of FFC are illustrated in FIG. 8, FIG. 9 and FIG. 10, respectively. FFC is a wiring film in which conductor wirings 5 arranged in parallel is fixed by sandwiching the wirings with two adhesive films 13 and laminating the films. When the adhesive film of the present invention is used, the adhesion is preferably performed in the ranges of 0.1 to 1 MPa of a laminating pressure and 100° C. to 140° C. of a laminating temperature.

FCC can be produced by placing an outer layer shield layer 14 made of a conductive adhesive layer and an aluminum metal foil on an outer layer of the wiring film of the present invention and connecting to a common grounding wire.

It is also possible that a multilayer wiring film is obtained by using the adhesive film having the adhesive layer of the present invention on both surfaces as a prepreg and laminating and adhering the wiring film in a plurality of layers.

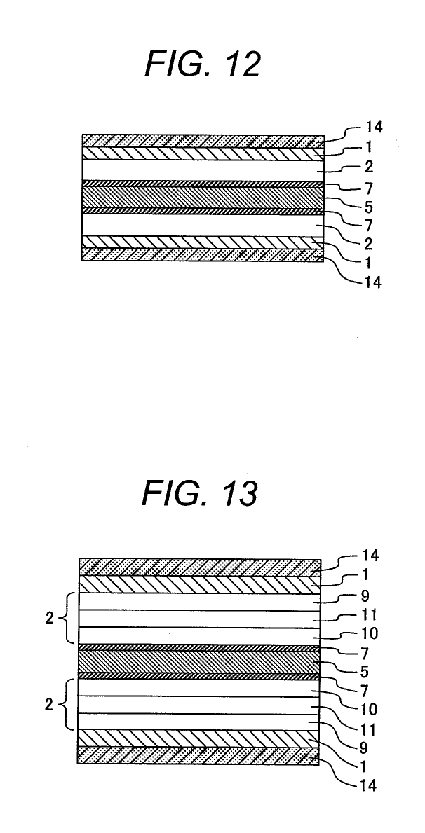

FIG. 12 is a cross-sectional view showing a structure of the wiring film of the present invention. The wiring film is constituted by a conductor layer 5 being as the center, a dissimilar metal layer 7 (which may include oxide or hydroxide), the adhesive layer 2 (constitution thereof has various forms as shown in FIGS. 1,2,3,4 and 7), the outer layer shield 14 and the substrate film 1.

A structure of a wiring film shown in FIG. 13 is a structure providing the first adhesive layer 9, the second adhesive layer 11 and the third adhesive layer 10 in addition to the constitution shown in FIG. 12.

### EXAMPLES

Hereinafter, the present invention is specifically described showing Examples and Comparative Examples. Reagents and evaluation methods are shown.

### (1) Test Samples

(A) Hydrogenated styrene-based elastomer: Tuftec (registered trademark) H1052, Elongation 700%, manufactured by Asahi Kasei Chemicals Corporation
(B) Hydrogenated styrene-based elastomer: Tuftec (registered trademark) H1227, Elongation 950%, manufactured by Asahi Kasei Chemicals Corporation
(C) Hydrogenated styrene-based elastomer: Tuftec (registered trademark) H1031, Elongation 650%, manufactured by Asahi Kasei Chemicals Corporation
(D) Polyphenylene ether-based polymer containing OHs at both ends: OPE, Polystyrene-converted molecular weight 1000, manufactured by MITSUBISHI GAS CHEMICAL COMPANY, INC.
(E) Isocyanate compound (1): Hexamethylene diisocyanate, manufactured by Wako Pure Chemical Industries, Ltd.
(F) Isocyanate compound (2): Polyhexamethylene diisocyanate, Duranate D201, Viscosity 1800 cps, NCO content 15.8% by weight, manufactured by Asahi Kasei Chemicals Corporation
(G) Isocyanate compound (3): Polyhexamethylene diisocyanate, Duranate D101, Viscosity 500 cps, NCO content 19.7% by weight, manufactured by Asahi Kasei Chemicals Corporation
(H) Isocyanate compound (4): Polyhexamethylene diisocyanate having isocyanurate structure, Duranate TPA-100, NCO content 23.1% by weight, manufactured by Asahi Kasei Chemicals Corporation
(I) Isocyanate compound (5): Tolylene 2,4-diisocyanate, manufactured by TOKYO CHEMICAL INDUSTRY CO., LTD.
(J) (I) Isocyanate compound (6): Isophorone diisocyanate, manufactured by TOKYO CHEMICAL INDUSTRY CO., LTD.
(K) Hydrogenated acrylonitrile-butadiene rubber, Zetpol (registered trademark) 2000L, Acrylonitrile content 36.2% by weight, manufactured by ZEON CORPORATION
(L) Hydrogenated acrylonitrile-butadiene rubber, Zetpol (registered trademark) 1020, Acrylonitrile content 44.2% by weight, manufactured by ZEON CORPORATION
(M) Hydrogenated acrylonitrile-butadiene rubber, Zetpol (registered trademark) 0020, Acrylonitrile content 49.2% by weight, manufactured by ZEON CORPORATION.
(N) Amorphous polyester: Vylon (registered trademark) GK 330, Glass transition temperature 16° C., Polystyrene-converted molecular weight 17000, manufactured by TOYOBO CO., LTD.
(O) Amorphous polyester: Vylon (registered trademark) 670, Glass transition temperature 7° C., Polystyrene-converted molecular weight 20000, manufactured by TOYOBO CO., LTD.
(P) Polyethylene terephthalate film: Thickness 20 μm
(Q) Rectangular copper wire: Width 0.5 mm, Thickness 35 μm, manufactured by Hitachi Cable, Ltd.
(R) Copper foil: Thickness 35 μm, JTC foil, manufactured by JX Nippon Mining & Metals Co. Ltd.
(S) KBM-602: N-2-(aminoethyl)-3-aminopropyltrimethoxy silane, manufactured by Shin-Etsu Chemical Co., Ltd.
(T) Flame retardant agent: Bis (pentabromophenyl)ethane, SAYTEX 8010, manufactured by ALBEMARLE JAPAN CORPORATION
(U) Catalyst: Dibutyl tin dilaurate (IV), manufactured by Wako Pure Chemical Industries, Ltd.

### (2) Preparation of Adhesive Varnish

Adhesive varnishes were prepared in the predetermined formulation ratios described in Table 2 to 5, Table 9-1 and Table 9-2.

### (3) Surface Treatment of Substrate Film

UV and ozone treatment is applied to a polyethylene terephthalate film having a thickness of 20 μm for predetermined time. Ten minutes, at which a contact angle becomes constant, was selected and treatment of the substrate film is performed. Relation between surface treatment time and a contact angle to water is shown in FIG. 11. Similarly, the UV and ozone treatment was also applied to the adhesive layer for 1 to 10 minutes, and thereby the adhesive layer became hydrophilic. Change in oxygen content and functional group content at the surface of the adhesive layer at this time is shown in Table 1.

TABLE 1

| | | UV and ozone treatment time | | | |
|---|---|---|---|---|---|
| | | Untreated | 1 min | 5 min | 10 min |
| Ratio of O/C peak intensity | | 0.01 | 0.08 | 0.15 | Not |
| Ratio of C1s | C—O | 0.02 | 0.05 | 0.1 | evaluated |
| subpeak intensity | C═O | 0.01 | 0.01 | 0.06 | |
| (C—H bond = 1) | O—C═O | 0 | 0.02 | 0.07 | |

### (4) Preparation of Adhesive Film

The adhesive varnish were applied on the surface treated substrate film using a bar coater having a predetermined gap. The coated film is dried at 80° C. for 20 minutes to prepare an adhesive film. Film thickness of the adhesive layers is shown in each Table.

### (5) Surface Treatment of Copper Foil

In order to evaluate adhesion force to a copper wire, predetermined treatment was applied to the shiny surface of a copper foil (JTC foil), and the adhesion force to the adhesive layer was evaluated. Hereinafter, a method for treatment is described. The JTC foil was immersed into 10% aqueous solution of sulfuric acid of 20° C. for 15 seconds, and then washed with flowing water for 1 minute. The JTC foil after wash was immersed into UTB 580-Z18, which is tin displacement plating solution manufactured by Ishihara Chemical Co., Ltd., heated at 60° C. for 5 minutes to apply tin displacement plating. Then, the plated sample was washed with flowing water for 1 minute and dried at 120° C. for 1 hour. As a result of observation of the cross-section of the copper foil, it was confirmed that a film thickness of the tin displacement plating was about 100 nm. It was also confirmed by a surface analysis with XPS that a layer having a thickness of several nanometer including tin oxide and tin hydroxide exists on the surface of the tin layer.

Predetermined 1% by weight of aqueous solution of the amine-based silane coupling agent was applied to the copper foil to which the tin displacement plating was applied was applied by a dip method. The applied wire was dried at 120° C. for 10 minutes to form an amine-based silane coupling agent layer. A film thickness of the amine-based silane coupling agent layer was about 0.07 μm.

Subsequently, the surface treatment was applied by applying a primer layer described in Table 7 onto the amine-based silane coupling agent layer with the bar coater in the predetermined thickness and drying the sample at 80° C. for 20 minutes.

### (6) Surface Treatment of Copper Foil 2

A copper foil was roughened with aqueous solution of ammonium persulfate and an oxide film was formed with aqueous solution of sodium perchlorate as a main component. Subsequently, reduction treatment was applied to the sample with aqueous solution of dimethylamino borane and dried (black oxide and reduction treatment).

### (7) Evaluation of Adhesion Force Between Substrate Film and Adhesive Layer

Surfaces at the adhesive layer side of two adhesive films were bonded together to adhere them by lamination under the conditions of a feed rate of 1 m/min, 120° C. and 0.4 MPa. The film after adhesion was cut out at a width of 1 cm and a peel test at 180° between the substrate and the adhesive layer was performed.

### (8) Evaluation of Adhesion Force Between Copper Foil and Adhesive Layer

The copper foil to which the surface treatment was applied was placed on the surface of the adhesive layer side of the adhesive film to adhere them by lamination under the conditions of a feed rate of 1 m/min, 120° C. and 0.4 MPa. Subsequently, a peel test at 180° between the copper foil and the adhesive film was performed. Peel strength between the copper foil and the adhesive film was observed as the adhesion force between a conductor wiring and the adhesive film.

### (9) Evaluation of Dielectric Characteristics of Adhesive Layer

Values at 10 GHz were measured by a cavity resonance method (Network analyzer Type 8722ES, manufactured by Agilent Technologies, Cavity resonator, manufactured by Kantoh Electronics Application and Development Inc.). Ten grams of the adhesive varnish was dried over a film made of polytetrafluoroethylene and a formed plate was prepared at 120° C. and 1 MPa. The sample was formed by cutting out from the formed plate in the size of 1.0×1.5×80 mm.

### (10) Evaluation of Flame Retardant Property

Surfaces at the adhesive layer side of two adhesive films were bonded together to adhere them to laminate under the conditions of a transfer rate of 1 m/min, 120° C. and 0.4 MPa. The film after adhesion was cut out at a width of 1.3 cm and a length of 16 cm and the sample was ignited with a gas burner. After ignition, the film was removed from flame. The evaluation is as follows. When flame of the film was extinguished within 5 seconds, the evaluation is “Good”, while when flame of the film was not extinguished, the evaluation is “Poor”.

### Comparative Example 1

Comparative Example 1 is an example of an adhesive film which used an adhesive layer not including an isocyanate compound. The evaluation results are shown in Table 2. It was confirmed that a dielectric constant of the adhesive layer was 2.2 and a dissipation factor of the adhesive layer was 0.0022, which were excellent, while adhesion force between the substrate film and the adhesive layer was 0.3 kN/m, which was low.

### Examples 1 to 6

Examples 1 to 6 are examples of adhesive films to which the various isocyanate compounds are added in predetermined amounts. The evaluation results are shown in Table 2. It was confirmed that when these Examples are compared to Comparative Example 1, the adhesion force to the substrate film was improved and the dielectric characteristics were hardly deteriorated by adding the isocyanate compounds. The adhesive film using the adhesive has both of excellent dielectric characteristics and adhesiveness. Therefore, the result which may be preferable as the adhesive for a wiring film for high-frequency use was obtained.

TABLE 2

| | | Comparative | | | | | | |
|---|---|---|---|---|---|---|---|---|
| Product name and compound name | | example 1 | Example 1 | Example 2 | Example 3 | Example 4 | Example 5 | Example 6 |
| Styrene-based elastomer | H1052 | 9.0 | 9.0 | 9.0 | 9.0 | 9.0 | 9.0 | 9.0 |
| Polyphenylene ether | OPE | 1.0 | 1.0 | 1.0 | 1.0 | 1.0 | 1.0 | 1.0 |
| Isocyanate | Hexamethylene | 0.0 | 0.5 | 0.0 | 0.0 | 2.0 | 0.0 | 0.0 |
| | diisocyanate | | | | | | | |
| | D101 | 0.0 | 0.0 | 0.5 | 0 | 0 | 0.2 | 1.0 |
| | D201 | 0.0 | 0.0 | 0.0 | 0.5 | 0.0 | 0.0 | 0.0 |
| | TAP-100 | 0.0 | 0.0 | 0.0 | 0.0 | 0.5 | 0.0 | 0.0 |
| | 2,4-Tolylene | 0.0 | 0.0 | 0.0 | 0.0 | 0.0 | 0.5 | 0.0 |
| | diisocyanate | | | | | | | |
| | Isophorone diisocyanate | 0.0 | 0.0 | 0.0 | 0.0 | 0.0 | 0.0 | 0.5 |
| Solvent | Toluene | 40.0 | 40.0 | 40.0 | 40.0 | 40.0 | 40.0 | 40.0 |

| | | | | | | | |
|---|---|---|---|---|---|---|---|
| Film thickness of adhesive layer (μm) | 20 | 20 | 20 | 20 | 20 | 20 | 20 |
| Surface treatment of substrate | Not treated | Treated | Treated | Treated | Treated | Treated | Treated |
| (Substrate: PET 20 μm) | | | | | | | |
| 180° peel strength between adhesive films (kN/m) | 0.30 | 0.50 | 0.67 | 0.72 | 0.67 | 0.71 | 0.67 |
| Relative permittivity @ 10 GHz | 2.2 | 2.2 | 2.2 | 2.2 | 2.2 | 2.2 | 2.2 |
| Dissipation factor @ 10 GHz | 0.0022 | 0.0022 | 0.0021 | 0.0022 | 0.0022 | 0.0023 | 0.0023 |

### Examples 7 to 11

Examples 7 to 11 are examples of adhesive films to which, as the isocyanate compound, poly hexamethylene diisocyanate (D101) was added. The evaluation results are shown in Table 3. It was confirmed that adhesion strength increased with increase in the amount of the isocyanate compound. The value of the dissipation factor slightly increases with increase in the isocyanate compound. However, within the range of this investigation, both of the dielectric characteristics and the adhesiveness are excellent. Therefore, the result in which the adhesive in this composition range is preferable for the wiring film for high-frequency use was obtained.

TABLE 3

| | | Comparative | | | | | |
|---|---|---|---|---|---|---|---|
| Product name and compound name | | example 1 | Example 7 | Example 8 | Example 9 | Example 10 | Example 11 |
| Styrene-based elastomer | H1052 | 9.0 | 9.0 | 9.0 | 9.0 | 9.0 | 9.0 |
| Polyphenylene ether | OPE | 1.0 | 1.0 | 1.0 | 1.0 | 1.0 | 1.0 |
| Isocyanate | D101 | 0.0 | 0.1 | 0.25 | 0.5 | 1.3 | 2.0 |
| Solvent | Toluene | 40.0 | 40.0 | 40.0 | 40.0 | 40.0 | 40.0 |

| | | | | | | |
|---|---|---|---|---|---|---|
| Film thickness of adhesive layer | 20 | 20 | 20 | 20 | 20 | 20 |
| (μm) | | | | | | |
| Surface treatment of substrate | Not treated | Treated | Treated | Treated | Treated | Treated |
| (Substrate: PET 20 μm) | | | | | | |
| 180° peel strength between | 0.30 | 0.48 | 0.54 | 0.67 | 0.81 | 0.48 |
| adhesive films (kN/m) | | | | | | |
| Relative permittivity @ 10 GHz | 2.2 | 2.2 | 2.2 | 2.2 | 2.2 | 2.2 |
| Dissipation factor @ 10 GHz | 0.0022 | 0.0022 | 0.0022 | 0.0022 | 0.0024 | 0.004 |

### Comparative Example 2

Comparative Example 2 is an example of an adhesive layer including 25 parts by weight of the polyphenylene ether-based polymer and 75 parts by weight of the styrene-based elastomer. The evaluation results are shown in Table 3. This adhesive layer includes no isocyanate compound and content of resin composition of polyphenylene ether-based polymer was increased. As a result, the adhesion force to the substrate film showed a lower value of 0.05 kN/m, which is lower than the adhesion force of the adhesive layer in Comparative Example 1. The dielectric constant and the dissipation factor of the adhesive layer showed slightly higher values of 2.3 and 0.005, respectively.

### Example 12

Example 12 is an example of an adhesive film to which, as the isocyanate compound, poly hexamethylene diisocyanate (D101) was added to the adhesive layer in Comparative Example 2. The evaluation results are shown in Table 3. It was confirmed that the adhesion force to the substrate film was improved to 0.52 kN/m by adding the isocyanate compound. At this time, the dielectric constant was 2.3 and the dissipation factor was 0.0052. Therefore, it was confirmed that the dielectric characteristics were hardly deteriorated compared to the dielectric characteristics in Comparative Example 2.

### Comparative Example 3

Comparative Example 3 is an example of an adhesive layer including 50 parts by weight of the polyphenylene ether-based polymer and 50 parts by weight of the styrene-based elastomer. The evaluation results are shown in Table 3. This adhesive layer includes no isocyanate compound and content of resin composition of polyphenylene ether-based polymer was increased. As a result, the adhesion force to the substrate film showed a low value of 0.05 kN/m. The dielectric constant and the dissipation factor of the adhesive layer showed values of 2.4 and 0.011, respectively. The value of the dissipation factor has an almost equal value to a conventional polyester-based adhesive layer.

### Example 13

Example 13 is an example of an adhesive film to which, as the isocyanate compound, poly hexamethylene diisocyanate (D101) was added to the adhesive layer in Comparative Example 3. The evaluation results are shown in Table 4. Although the isocyanate compound was added, the adhesion force was hardly improved. As a result, an effect of addition of the isocyanate compound was not confirmed. These dielectric characteristics also showed values similar to the dielectric characteristics in Comparative Example 3. From the comparison of Example 12 to Comparative Example 3 and Example 13, the result in which the formulation ratios of the styrene-based elastomer and the polyphenylene ether-based polymer were probably preferable in the range of 75/25 parts by weight to 95/5 parts by weight was obtained.

TABLE 4

| | | Comparative | | Comparative | |
|---|---|---|---|---|---|
| Product name and compound name | | example 2 | Example 12 | example 3 | Example 13 |
| Styrene-based elastomer | H1052 | 7.5 | 7.5 | 5.0 | 5.0 |
| Polyphenylene ether | OPE | 2.5 | 2.5 | 5.0 | 5.0 |
| Isocyanate | D101 | 0.0 | 1.3 | 0.0 | 1.3 |
| Solvent | Toluene | 40.0 | 40.0 | 40.0 | 40.0 |

| | | | | |
|---|---|---|---|---|
| Film thickness of adhesive layer (μm) | 20 | 20 | 20 | 20 |
| Surface treatment of substrate (Substrate: PET 20 μm) | Not treated | Treated | Not treated | Treated |
| 180° peel strength between adhesive films (kN/m) | 0.05 | 0.52 | 0.05 | 0.12 |
| Relative permittivity @ 10 GHz | 2.3 | 2.3 | 2.4 | 2.4 |
| Dissipation factor @ 10 GHz | 0.005 | 0.0052 | 0.011 | 0.011 |

### Examples 14 to 19

Examples 14 to 17 are examples of adhesives to which, as a curing catalyst for the isocyanate compound, dibutyl tin dilaurate (IV) was added. The evaluation results are shown in Table 5. It was confirmed that the adhesion force was further enhanced compared to the adhesion force in Example 10 by an effect of addition of the curing catalyst. In addition, deterioration of the dielectric characteristics was not observed. Examples 18 to 19 are examples of adhesives in which a small amount of flame retardant agent was added to the adhesive in Example 17. It was confirmed that the addition of the flame retardant agent provided tack-free property. At this time, the dielectric characteristics and the adhesion force were hardly changed. As described above, the adhesives of these examples had both of the excellent dielectric characteristics and the adhesiveness. Therefore, the result which was probably preferable as adhesives for wiring films for high-frequency use was obtained.

TABLE 5

| Product name and compound name | | Example 10 | Example 14 | Example 15 | Example 16 | Example 17 | Example 18 | Example 19 |
|---|---|---|---|---|---|---|---|---|
| Styrene-based | H1052 | 9.0 | 9.0 | 9.0 | 9.0 | 9.0 | 9.0 | 9.0 |
| elastomer | | | | | | | | |
| Polyphenylene ether | OPE | 1.0 | 1.0 | 1.0 | 1.0 | 1.0 | 1.0 | 1.0 |
| Isocyanate | D101 | 1.3 | 1.3 | 1.3 | 1.3 | 1.3 | 1.3 | 1.3 |
| Flame retardant agent | SAYTEX8010 | 0.0 | 0.0 | 0.0 | 0.0 | 0.0 | 0.6 | 2.2 |
| Curing catalyst | Dibutyl tin dilaurate (IV) | 0.00 | 0.02 | 0.04 | 0.08 | 0.20 | 0.20 | 0.20 |
| Solvent | Toluene | 40.0 | 40.0 | 40.0 | 40.0 | 40.0 | 40.0 | 40.0 |

| | | | | | | | |
|---|---|---|---|---|---|---|---|
| Film thickness of adhesive layer (μm) | 20 | 20 | 20 | 20 | 20 | 20 | 20 |
| Surface treatment of substrate | Treated | Treated | Treated | Treated | Treated | Treated | Treated |
| (Substrate: PET 20 μm) | | | | | | | |
| 180° peel strength between adhesive films (kN/m) | 0.81 | 1.02 | 1.02 | 1.12 | 0.99 | 1.11 | 0.92 |
| Relative permittivity @ 10 GHz | 2.2 | 2.2 | 2.2 | 2.2 | 2.2 | 2.2 | 2.2 |
| Dissipation factor @ 10 GHz | 0.0024 | 0.0024 | 0.0024 | 0.0024 | 0.0024 | 0.0024 | 0.0024 |
| Tack free property of adhesive layer | Poor | Poor | Poor | Poor | Poor | Good | Good |

### Examples 20 to 22

Examples 20 to 22 are examples in which a specific flame retardant agent was added the adhesive in Example 10. The evaluation results are shown in Table 6. It was confirmed that the dissipation factor was decreased by adding the specific flame retardant agent and the adhesive film became flame retardant by adding 100 parts by weight or more of the flame retardant agent when the total weight of the resin component is 100 parts by weight. It became clear from the above description that the application of the adhesive to which the specific flame retardant agent was added contributed to improvement of safety for the wiring film for high-frequency use.

TABLE 6

| | | Example | Example | Example | Example |
|---|---|---|---|---|---|
| Product name and compound name | | 10 | 20 | 21 | 22 |
| Styrene-based elastomer | H1052 | 9.0 | 9.0 | 9.0 | 9.0 |
| Polyphenylene ether | OPE | 1.0 | 1.0 | 1.0 | 1.0 |
| Isocyanate | D101 | 1.3 | 1.3 | 1.3 | 1.3 |
| Flame retardant agent | SAYTEX8010 | 0.0 | 6.8 | 11.3 | 22.6 |
| Solvent | Toluene | 40.0 | 72 | 72 | 72 |

| | | | | |
|---|---|---|---|---|
| Film thickness of adhesive layer (μm) | 20 | 20 | 20 | 20 |
| Surface treatment of substrate (Substrate: PET 20 μm) | Treated | Treated | Treated | Treated |
| 180° peel strength between adhesive films (kN/m) | 0.81 | 0.4 | 0.3 | 0.23 |
| Relative permittivity @ 10 GHz | 2.2 | 2.3 | 2.3 | 2.4 |
| Dissipation factor @ 10 GHz | 0.0024 | 0.002 | 0.0019 | 0.0016 |
| Flame retardant property of adhesive film | Poor | Poor | Good | Good |

### Examples 23 to 26

Examples 23 to 26 are examples of adhesive films made by placing the adhesive of Example 16, which does not include the flame retardant agent, as a primer layer and further laminating the adhesive of Example 22, which includes the flame retardant agent, on the primer layer as an adhesive layer. The evaluation results are shown in Table 7. It became clear that both of the flame retardant property and the adhesion force were satisfied by placing the primer layer. Both of the adhesives in Example 16 and Example 22 have excellent dielectric characteristics, so that the adhesive films of the present invention have all of excellent dielectric characteristics, adhesiveness and flame retardant property. Consequently, these adhesive films are preferable for the wiring film for high-frequency use.

TABLE 7

| Layer constitution | | Comparative | Example | Example | Example | Example |
|---|---|---|---|---|---|---|
| of adhesive film | Applied material | example 4 | 23 | 24 | 25 | 26 |
| Thickness of primer layer | Adhesive in Example 16 | 0 | 1 | 6 | 12 | 18 |
| for substrate (μm) | | | | | | |
| Thickness of adhesive layer with highly | Adhesive in Example 22 | 20 | 20 | 20 | 20 | 20 |
| filled flame retardant agent (μm) | | | | | | |

| | | | | | |
|---|---|---|---|---|---|
| Surface treatment of substrate (Substrate: PET 20 μm) | Treated | Treated | Treated | Treated | Treated |
| 180° peel strength between adhesive films (kN/m) | 0.23 | 0.71 | 1.02 | 1.19 | 1.21 |
| Flame retardant property of adhesive film | Good | Good | Good | Good | Good |

### Comparative Example 5

In comparative Example 5, adhesion force between the adhesive film in Example 24 and a copper foil to which silane coupling treatment was applied was evaluated. The evaluation results are shown in Table 8. Since the flame retardant agent was highly filled in the second adhesive layer, the sample showed low adhesion force.

### Example 27 to 30

Example 27 to 30 are adhesion examples between the copper foil made by laminating the adhesive in Example 16 on a copper foil as an primer layer for a conductor wiring and the adhesive film described in Example 24. The results are listed in Table 8. Example 27 to 30 showed higher adhesion force than the adhesion force of Comparative Example 5, which did not have a primer layer for a conductor wiring on a copper foil. By this evaluation, it was confirmed that placement of the primer layer on a copper wiring contributed improvement of the adhesion force between the copper wiring and the adhesive layer including the flame retardant agent. Since the wiring films of these Examples having the primer layer for the conductor wiring has flame retardant property, a low dielectric constant, a low dissipation factor had high adhesiveness, the wiring films are preferable for the wiring film for high-frequency use.

### Example 31

Example 31 is an adhesion example between a copper foil treated by the black oxide and reduction treatment and the adhesive film described in Example 24. The results are listed in Table 8. This sample showed high adhesion force to the adhesive layer including the flame retardant agent by roughening the surface of the copper foil. By this evaluation, it was confirmed that the roughening treatment of the surface of a copper wiring contributed improvement of the adhesion force between the adhesive layer including the flame retardant agent and the copper wiring. Since the wiring film of this Example made by roughening the surface of the copper wiring of the present invention has flame retardant property, a low dielectric constant, a low dissipation factor had high adhesiveness, the film is preferable for the wiring film for high-frequency use.

TABLE 8

| | | Comparative | Example | Example | Example | Example | Example |
|---|---|---|---|---|---|---|---|
| Layer constitution on copper film | Applied material | example 5 | 27 | 28 | 29 | 30 | 31 |
| Thickness of tin layer (μm) | Tin for displacement | 0.1 | | | | | 0 |
| | plating | | | | | | |
| Thickness of silane coupling agent | KBM602 | 0.07 | | | | | 0 |
| (μm) | | | | | | | |
| Thickness of primer layer on wiring | Adhesive in Example 16 | 0 | 1 | 6 | 12 | 18 | 0 |
| (μm) | | | | | | | |

| | | | | | | |
|---|---|---|---|---|---|---|
| Black oxide and reduction treatment layer | Not exist | Not exist | Not exist | Not exist | Not exist | Exist |
| 180° peel strength between adhesive film in Example 24 and | 0.05 | 0.6 | 0.62 | 0.72 | 0.72 | 0.9 |
| conductor (kN/m) | | | | | | |

### Comparative Example 6

Comparative Example 6 is an adhesion example between an adhesive film in which the adhesive in Example 18 acts as a primer layer for the substrate and the adhesive in Example 22 acts as an adhesive layer, and a copper foil to which tin plating to which coupling treatment is not applied is applied. The results are listed in Tables 9-1 and 9-2. Since the flame retardant agent was highly filled in the adhesive in Example 22, the adhesion force to the copper foil showed a low value.

### Example 32 to 34

Examples 32 to 34 are examples in which an acrylonitrile-butadiene rubber is placed on the adhesive layer in Comparative example 6 as a primer for the conductor wiring. It was confirmed that although the adhesion force to the copper foil to which the tin plating was applied was improved, the adhesion force was unstable and the adhesion force between the films was lowered.

### Example 35 to 43

Example 35 to 43 are examples in which adhesives to which the hydrogenated styrene-based elastomer and the acrylonitrile-butadiene rubber the amorphous polyester are added are used for a primer for the conductor wiring. It was confirmed that both of the adhesion force to the copper foil and the adhesion force between the films were improved by formulating the styrene-based elastomer. Since the wiring film using the adhesive films of these Examples has flame retardant property, a low dielectric constant, a low dissipation factor and high adhesiveness, the film is preferable for the wiring film for high-frequency use.

TABLE 9-1

| | | | Comparative | Example | Example | Example | Example | Example |
|---|---|---|---|---|---|---|---|---|
| | Product name and compound name | | example 6 | 32 | 33 | 34 | 35 | 36 |
| Primer composition | Styrene-based elastomer | H1052 | Without primer | 0 | 0 | 0 | 9.5 | 9.5 |
| for conductor wiring | Acrylonitrile-butadiene | Zetpol2000L | composition for | 10 | 0 | 0 | 0.5 | 0 |
| | | Zetpol1020 | conductor wiring | 0 | 10 | 0 | 0 | 0 |
| | | Zetpol0020 | | 0 | 0 | 10 | 0 | 0.5 |
| | Amorphous polyester | VylonGK330 | | 0 | 0 | 0 | 0 | 0 |
| | | Vylon 670 | | 0 | 0 | 0 | 0 | 0 |
| | Solvent | Toluene | | 0 | 0 | 0 | 70 | 70 |
| | | Cyclohexanone | | 90 | 90 | 90 | 30 | 30 |

| | | | | | | | |
|---|---|---|---|---|---|---|---|
| Constitution of multilayer | Film thickness of primer for conductor | 0 | 5 | 5 | 5 | 5 | 5 |
| adhesive layer | wiring (μm) | | | | | | |
| | Thickness of adhesive layer with highly | 25 | 25 | 25 | 25 | 25 | 25 |
| | filled flame retardant agent in | | | | | | |
| | Example 22 (μm) | | | | | | |
| | Thickness of adhesive layer with highly | 10 | 10 | 10 | 10 | 10 | 10 |
| | filled flame retardant agent in | | | | | | |
| | Example 18 (μm) | | | | | | |
| Evaluation result of | 180° peel strength between adhesive films | 1.2 | 0.2-0.5 | 0.3-1.0 | 0.2-0.4 | 1.1 | 1 |
| adhesion force | (kN/m) | | | | | | |
| | Peel strength to copper foil to which tin | 0.05 | 0.3-0.5 | 0.4-0.6 | 0.3-0.5 | 0.4 | 0.6 |
| | plating is applied (kN/m) | | | | | | |

| | | | | | | |
|---|---|---|---|---|---|---|
| Flame retardant property of adhesive film | Good | Good | Good | Good | Good | Good |

TABLE 9-2

| | | | Example | Example | Example | Example | Example | Example | Example |
|---|---|---|---|---|---|---|---|---|---|
| | Product name and compound name | | 37 | 38 | 39 | 40 | 41 | 42 | 43 |
| Primer composition for | Styrene-based elastomer | H1052 | 9.9 | 9.75 | 9.5 | 9 | 7.5 | 9 | 9 |
| conductor wiring | Acrylonitrile-butadiene | Zetpol2000L | 0 | 0 | 0 | 0 | 0 | 0 | 0 |
| | | Zetpol1020 | 0.1 | 0.25 | 0.5 | 1 | 2.5 | 0.5 | 0.5 |
| | | Zetpol0020 | 0 | 0 | 0 | 0 | 0 | 0 | 0 |
| | Amorphous polyester | VylonGK330 | 0 | 0 | 0 | 0 | 0 | 0.5 | 0 |
| | | Vylon 670 | 0 | 0 | 0 | 0 | 0 | 0 | 0.5 |
| | Solvent | Toluene | 70 | 70 | 70 | 70 | 70 | 70 | 70 |
| | | Cyclohexanone | 30 | 30 | 30 | 30 | 30 | 30 | 30 |

| | | | | | | | | |
|---|---|---|---|---|---|---|---|---|
| Constitution | Film thickness of primer for conductor | 5 | 5 | 5 | 5 | 5 | 5 | 5 |
| of multilayer | wiring (μm) | | | | | | | |
| adhesive layer | Thickness of adhesive layer with highly | 25 | 25 | 25 | 25 | 25 | 25 | 25 |
| | filled flame retardant agent in | | | | | | | |
| | Example 22 (μm) | | | | | | | |
| | Thickness of adhesive layer with highly | 10 | 10 | 10 | 10 | 10 | 10 | 10 |
| | filled flame retardant agent in | | | | | | | |
| | Example 18 (μm) | | | | | | | |
| Evaluation | 180° peel strength between adhesive films | 1.1 | 1.4 | 1.6 | 1.3 | 1.1 | 1.3 | 1.3 |
| result of | (kN/m) | | | | | | | |
| adhesion force | Peel strength to copper foil to which tin | 0.4 | 0.5 | 0.6 | 0.5 | 0.5 | 0.7 | 0.7 |
| | plating is applied (kN/m) | | | | | | | |

| | | | | | | | |
|---|---|---|---|---|---|---|---|
| Flame retardant property of adhesive film | Good | Good | Good | Good | Good | Good | Good |

### Example 44 to 46

Examples 44 to 46 are examples which improve adhesion force to the conductor wiring by hydrophilic treatment to the second adhesive layer. The results are shown in Table 10. The adhesion force of the adhesive film in Example 6 in which the adhesive layer described in Example 18 was used as the first adhesive layer and the adhesive in Example 22 was used as the second adhesive layer to the copper foil was 0.05 kN/m, which is low, while Examples 44 to 46 to which the hydrophilic treatment with UV and ozone was applied showed a high adhesion force of 0.5 kN/m or higher. Since the adhesive films of these Examples have flame retardant property, a low dielectric constant, a low dissipation factor and high adhesiveness, the film is preferable for the wiring film for high-frequency use.

TABLE 10

| | | Com- | | | |
|---|---|---|---|---|---|
| | | parative | Example | Example | Example |
| | Used material and surface treatment | example 6 | 44 | 45 | 46 |
| Constitution | UV and ozone treatment time to surface of adhesive layer in Example 20 (min) | 0 | 1 | 5 | 10 |
| of | Thickness of adhesive layer with highly filled flame retardant agent in Example 20 (μm) | 25 | 25 | 25 | 25 |
| multilayer | Thickness of adhesive layer with highly filled flame retardant agent in Example 18 (μm) | 10 | 10 | 10 | 10 |
| adhesive | | | | | |
| layer | | | | | |
| Evaluation | 180° peel strength between adhesive films (kN/m) | 1.2 | 1.1 | 1.1 | 1.1 |
| result of | Peel strength to copper foil to which tin plating is applied (kN/m) | 0.05 | 0.5 | 0.6 | 0.7 |
| adhesion | | | | | |
| force | | | | | |

### Example 47

In Example 47, a manufacturing example of FFC was shown.

(A) The adhesive film prepared in Example 24 was cut out in the size of 20×150 mm, and the substrate side of the adhesive film was placed on a glass-epoxy substrate having a size of 30×200 mm and attached by a polyimide tape.

(B) Ten copper wirings to which black oxide and reduction treatment was applied were placed in parallel on the adhesive layer side of the adhesive film on the glass-epoxy substrate in such a way that center of the wirings were arranged at 1 mm intervals, and both ends of the copper wirings were fixed with the polyimide tape.

(C) The adhesive film prepared in Example 24 was cut out in the size of 20×130 mm, and this film is overlapped over the above-described copper wirings, in which the adhesive layer is directed to the side of copper wirings, and the ends of longer sides of the film was fixed with the polyimide tape.

(D) Whole of the glass-epoxy substrate was covered with polytetrafluoroethane film and two adhesive films on the glass-epoxy substrate were adhered by lamination treatment to obtain a wiring film. The lamination condition was set to a feed rate of 1.0 m/min, a laminate temperature of 120° C. and a laminate pressure of 0.4 MPa.

(E) The wiring film was separated from the polytetrafluoroethane film and the glass-epoxy substrate, and both of short sides and both of long side were cut and removed in 5 mm and 3 mm, respectively, to prepare a wiring film having a width of 14 mm and a length of 140 mm.

(F) Subsequently, a shield layer was placed by covering the substrate film on the wiring film with an aluminum foil with a conductive adhesive layer.

(G) A model FFC was prepared by connecting the shield layer to a part of wirings with silver paste. This flexible flat cable did not generate interlayer delamination by folding the cable. The adhesive layer of this cable had a low dielectric constant and a dissipation factor and has flame retardant property, the cable was preferable for a connection cable for high-frequency devices.

The low dielectric constant adhesive of the present invention and the adhesive film using the adhesive can be applicable for an adhesive and an adhesive film for a wiring film and a flexible flat cable. The wiring film and the flexible flat cable using the adhesive has low dielectric loss in the adhesive layer and has excellent adhesion force to the conductor wiring and the substrate film. Due to these properties, the adhesive and the adhesive film are suitable in use for a wiring material for high-frequency devices.

1. A thermoplastic resin composition comprising:
(I) a polyphenylene ether-based polymer having hydroxyl groups in its chemical structure and having 2,6-dimethylphenylene ether as a repeating unit;
(II) an isocyanate compound having a plurality of isocyanate groups in its structure; and
(III) a hydrogenated styrene-based elastomer as essential components; or the composition comprising:
(III) the hydrogenated styrene-based elastomer; and
(IV) a reaction product of (I) and (II) as essential components.

2. The thermoplastic resin composition according to claim 1,
wherein the polyphenylene ether-based polymer is a diol compound having hydroxyl groups in both ends thereof and the isocyanate compound is a diisocyanate compound.

3. The thermoplastic resin composition according to claim 1,
further comprising a catalyst which accelerates a reaction of isocyanate groups with hydroxyl groups, amino groups, amide groups and carboxyl groups.

4. The thermoplastic resin composition according to claim 1,
wherein the composition comprises 75 to 90 parts by weight of the hydrogenated styrene-based elastomer, 10 to 25 parts by weight of the polyphenylene ether-based polymer having 2,6-dimethylphenylene ether as the repeating unit, and 1 to 20 parts by weight of the isocyanate compound having the isocyanate groups in its structure.

5. The thermoplastic resin composition according to claim 4,
wherein the catalyst is added to the thermoplastic resin composition and an amount of the added catalyst is 0.1 to 2 parts by weight to 100 parts by weight of a total amount of the resin components.

6. The thermoplastic resin composition according to claim 1,
further comprising a hydrogenated acrylonitrile-butadiene rubber and/or an amorphous polyester in addition to the hydrogenated styrene-based elastomer.

7. The thermoplastic resin composition according to claim 6,
wherein the composition comprises 50 to 99 parts by weight of the hydrogenated styrene-based elastomer and 1 to 50 parts by weight of a total amount of the hydrogenated acrylonitrile-butadiene rubber or/and the amorphous polyester.

8. The thermoplastic resin composition according to claim 1,
further comprising a flame retardant agent represented by Formula 1 and/or Formula 2.

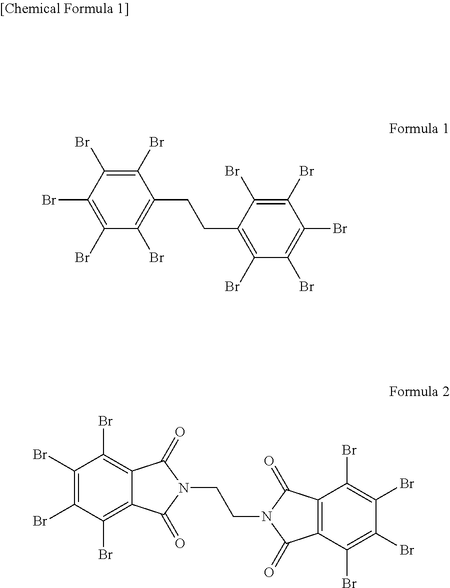

9. The thermoplastic resin composition according to claim 8,
wherein an amount of the added flame retardant agent is 100 to 300 parts by weight to 100 parts by weight of a total amount of the resin components in the thermoplastic resin composition.

10. An adhesive film in which an adhesive layer having a thickness of 10 μm to 104 μm made of a thermoplastic resin composition comprising:
(I) a polyphenylene ether-based polymer having hydroxyl groups in its chemical structure and having 2,6-dimethylphenylene ether as a repeating unit;
(II) an isocyanate compound having a plurality of isocyanate groups in its structure; and
(III) a hydrogenated styrene-based elastomer as essential components; or the composition comprising:
(III) the hydrogenated styrene-based elastomer; and
(IV) a reaction product of (I) and (II) as essential components is laminated on a substrate film having a thickness of 10 to 300 μm.

11. The adhesive film according to claim 10,
wherein the substrate film is one of the films selected from a polypropylene film, a polyethylene terephthalate film, a polyphenylene sulfide film, a polyimide film, a polyamide-imide film, a polyether ether ketone film, a liquid crystalline polymer film and combinations thereof.

12. The adhesive film according to claim 10,
wherein the thermoplastic resin composition comprises a hydrogenated acrylonitrile-butadiene rubber and/or an amorphous polyester in addition to the hydrogenated styrene-based elastomer.

13. The adhesive film according to claim 10,
wherein the film comprises a first adhesive layer having a thermoplastic resin composition in which a content of a flame retardant agent is 0 to 90 parts by weight to 100 parts by weight of a total amount of the resins; and a second adhesive layer formed thereon having a thermoplastic resin composition in which a content of a flame retardant agent is 100 parts by weight or more to 100 parts by weight of a total amount of the resins; and
wherein these adhesive layers are laminated on the substrate film.

14. The adhesive film according to claim 13,
wherein the first adhesive layer and the second adhesive layer are laminated by a plurality of layers.

15. The adhesive film according to claim 10,
wherein an interface of the adhesive layer and the substrate film in the adhesive film comprises at least any one of chemical structures selected from a hydroxyl group, a carboxyl group, an amino group, a urethane bond, a urea bond and an amide bond.

16. The adhesive film according to claim 10,
wherein a third adhesive layer having a high polar layer comprising a compound having any one or more of the functional groups selected from a hydroxyl group, a carboxyl group, a nitrile group, a ketone group, an amide group and an amino group is laminated on the second adhesive layer.

17. The adhesive film according to claim 16,
wherein the third adhesive layer comprises a polymer selected from a hydrogenated acrylonitrile-butadiene rubber, a hydrogenated styrene-based elastomer and an amorphous polyester.

18. The adhesive film according to claim 10,
wherein the third adhesive layer further comprises a flame retardant agent illustrated by Formula 1 or Formula 2.

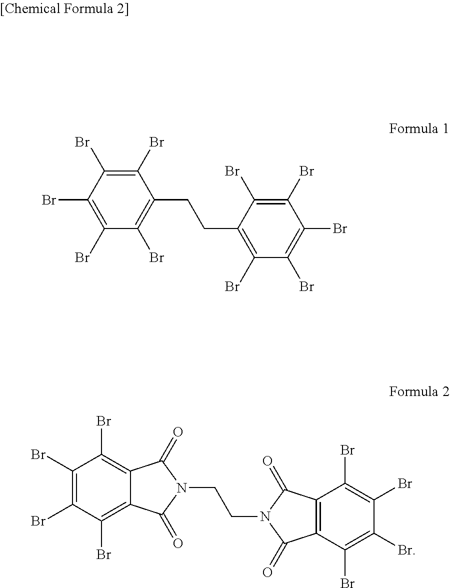

19. The adhesive film according to claim 13,
wherein the third adhesive layer is a high polar layer formed by hydrophilic treatment of the surface of the second adhesive layer.

20. The adhesive film according to claim 19,
wherein the third adhesive layer is a high polar layer formed by any hydrophilic treatment selected from UV and ozone treatment, corona treatment and plasma treatment to the second adhesive layer.

21. The adhesive film according to claim 10,
wherein a thickness of the first adhesive layer is 1 to 18 μm, a thickness of the second adhesive layer being 9 to 99 μm, and a thickness of the third adhesive layer being 0 μm to 10 μm.

22. The adhesive film according to claim 10,
wherein a dielectric constant is 2.3 to 2.7 and a dissipation factor is 0.0015 to 0.005 in combined dielectric characteristics of the adhesive layer.

23. A wiring film integrating a column of conductors arranging a plurality of conductors in parallel and a surface of the column of conductors by adhering from both sides through an adhesive layer with two adhesive films,
wherein the adhesive layer is made of a thermoplastic resin composition comprising:
(I) a polyphenylene ether-based polymer having hydroxyl groups in its chemical structure and having 2,6-dimethylphenylene ether as a repeating unit;
(II) an isocyanate compound having a plurality of isocyanate groups in its structure; and
(III) a hydrogenated styrene-based elastomer as essential components; or the composition comprising:
(III) the hydrogenated styrene-based elastomer; and
(IV) a reaction product of (I) and (II) as essential components.

24. The wiring film according to claim 23,
wherein the conductor wiring is made of copper; the surface thereof having a dissimilar metal layer selected from tin, zinc, cobalt, nickel and chromium; a surface of the dissimilar metal layer further having an oxide or a hydroxide layer made of the corresponding metal, if necessary; and the oxide or the hydroxide layer having any one of a silane coupling agent layer having amino groups, hydroxyl groups or isocyanate groups and a reaction residue of the silane coupling agent with the isocyanate compound on the oxide or the hydroxide layer.

25. The wiring film according to claim 23,
wherein a conductor surface of the wiring film is subjected to roughening treatment.

26. The wiring film according to claim 23,
wherein covalent bonds and/or a high polar layer are comprised between the adhesive layer and the conductor wiring.

27. A wiring film integrating a column of conductors arranging a plurality of conductors in parallel and a surface of the column of conductors by adhering from both sides through an adhesive layer with two adhesive films, wherein an adhesive film according to claim 10 is used as the adhesive film.

28. The wiring film according to claim 23,
wherein an aluminum foil layer is placed on an outer layer of a substrate film through a conductive adhesive layer and the aluminum foil layer is electrically connected to at least one of the conductor wiring.

29. A multilayer wiring film made by alternatively laminating a wiring film having a wiring pattern on at least one surface thereof and an adhesive film having adhesive layers on both surfaces thereof, wherein the adhesive layer is made of a thermoplastic resin composition comprising:
(I) a polyphenylene ether-based polymer having hydroxyl groups in its chemical structure and having 2,6-dimethylphenylene ether as a repeating unit;
(II) an isocyanate compound having a plurality of isocyanate groups in its structure; and
(III) a hydrogenated styrene-based elastomer as essential components; or the composition comprising:
(III) the hydrogenated styrene-based elastomer; and
(IV) a reaction product of (I) and (II) as essential components.

30. A multilayer wiring film made by alternatively laminating a wiring film having a wiring pattern on at least one surface thereof and an adhesive film having adhesive layers on both surfaces thereof, the adhesive film is an adhesive film according to claim 10.
